(19) United States
(12) Patent Application Publication
(10) Pub. No.: US 2007/0215991 A1
(43) Pub. Date: Sep. 20, 2007

(54) TAPE

(76) Inventors: Chyh-Yih Chang, Taipei County (TW); Kun-Hsien Tsai, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,868

(22) Filed: May 17, 2006

(30) Foreign Application Priority Data
Mar. 14, 2006 (TW) 95108514

(51) Int. Cl. H01L 23/495

(52) U.S. Cl. 257/668

(57) ABSTRACT

A tape with a chip-bonding area is provided. The tape is suitable for a chip on film configuration, wherein a chip is suitable for being disposed on the tape and in the chip-bonding area. The tape includes a dielectric base film, a first wiring pattern, and at least a second wiring pattern. The first wiring pattern is disposed on the dielectric base film and has multiple inner leads disposed in the chip-bonding area. The second wiring pattern is disposed on the dielectric base film and in the chip-bonding area. The chip is suitable for being electrically connected to at least a part of the inner leads and being disposed above the second wiring pattern.

### CROSS-REFERENCE TO RELATED APPLICATION

This application claims the priority benefit of Taiwan application serial no. 95108514, filed on Mar. 14, 2006. All disclosure of the Taiwan application is incorporated herein by reference.

### BACKGROUND OF THE INVENTION

1. Field of Invention

The present invention relates to a tape. More particularly, the present invention relates to a tape suitable for a chip on film configuration (COF configuration).

2. Description of Related Art

Tape automated bonding (TAB) technology for fitting a chip onto a tape is commonly used in personal computer screens or in liquid crystal displays of portable devices, such as mobile phones. The package configuration formed by the TAB technology is generally divided into a tape carrier package configuration (TCP configuration) and a COF configuration. The tape for the TCP configuration is different from that for the COF configuration. The difference lies mainly in that the former tape has a device hole to suspend the inner leads, and the latter one has the inner leads supported by a dielectric base film usually made of polymide.

FIG. 1A is a top view of a conventional TCP configuration. FIG. 1B is a schematic sectional view of the TCP configuration of FIG. 1A along line A-A. Referring to FIGS. 1A and 1B, the TCP configuration 100 comprises a chip 110, a tape 120, a plurality of bumps 130, and an encapsulant 140. The chip 110 is disposed on the tape 120, and the tape 120 comprises a dielectric base film 122, a wiring pattern 124, and a solder resist 126. The dielectric base film 122 has a device hole 122a, and the wiring pattern 124 is disposed on the dielectric base film 122. A plurality of inner leads 124a of the wiring pattern 124 is disposed in the device hole 122a, and the chip 110 is electrically connected to the inner leads 124a via the bumps. The solder resist 126 covers a part of the wiring pattern 124, and the encapsulant 140 of resin encapsulates the chip 110, the inner leads 124a and the bumps 130.

FIG. 2A is a top view of another conventional COF configuration. FIG. 2B is a schematic sectional view of the COF configuration of FIG. 2A along line B-B. Referring to FIGS. 2A and 2B, the COF configuration 200 comprises a chip 210, a tape 220, a plurality of bumps 230, and an encapsulant 240. The chip 210 is disposed on the tape 220, and the tape 220 comprises a dielectric base film 222, a wiring pattern 224, a dummy pattern 226, and a solder resist 228. The wiring pattern 224 and the dummy pattern 226 are disposed on the dielectric base film 222. The chip 210 is electrically connected to a plurality of inner leads 224a of the wiring pattern 224 via the bumps 230. The solder resist 228 covers a part of the wiring pattern 224, and the encapsulant 240 made of resin encapsulates the chip 210, the inner leads 224a , the dummy pattern 226, and the bumps 230.

Since during the process of encapsulating with the encapsulant 240, the dummy pattern 226 is used to reduce the flow velocity of the encapsulant 240, when the encapsulant 240 flows through the interval between the chip 210 and the dielectric base film 222, the number of bubbles generated inside the encapsulant 240 is reduced.

However, for either the tape 120 of the conventional TCP configuration 100 or the tape 220 of the COF configuration 200, no wiring patterns are above or below the chips 110, 210 outside the bonding areas of the chips 110, 210 and the inner leads 124a, 224a.

### SUMMARY OF THE INVENTION

The object of the present invention is to provide a tape that has wiring patterns other than the inner leads in the chip-bonding area.

In order to achieve this and other objects, the present invention provides a tape with a chip-bonding area. The tape is suitable for a COF configuration, wherein a chip is suitable for being disposed on the tape and in the chip-bonding area. The tape comprises a dielectric base film, a first wiring pattern, and at least a second wiring pattern. The first wiring pattern is disposed on the dielectric base film and has a plurality of inner leads disposed in the chip-bonding area. The second wiring pattern is disposed on the dielectric base film and in the chip-bonding area. The chip is suitable for being electrically connected to at least a part of the inner leads and being disposed above the second wiring pattern.

In one embodiment of the present invention, the aforementioned second wiring pattern is, for example, rectangular.

In one embodiment of the present invention, the aforementioned second wiring pattern comprises a trunk part and a plurality of protruding parts electrically connected to the trunk part.

In one embodiment of the present invention, the aforementioned second wiring pattern comprises a trunk part and a plurality of protruding parts electrically connected to the trunk part. Moreover, the protruding parts may be disposed on one side of the trunk part.

In one embodiment of the present invention, the aforementioned second wiring pattern comprises a trunk part and a plurality of protruding parts electrically connected to the trunk part. Moreover, the protruding parts may be disposed on two opposite sides of the trunk part.

In one embodiment of the present invention, the aforementioned second wiring pattern may have at least one opening.

In one embodiment of the present invention, the aforementioned second wiring pattern may have at least one opening. Moreover, the opening may be rectangular.

In one embodiment of the present invention, the aforementioned second wiring pattern may have at least one opening. Moreover, the opening may be spiral-shaped.

In one embodiment of the present invention, the aforementioned inner leads, for example, are not electrically connected to the second wiring pattern.

In one embodiment of the present invention, one of the aforementioned inner leads, for example, is electrically connected to the second wiring pattern.

In one embodiment of the present invention, the aforementioned tape further includes a solder resist covering a part of the first wiring pattern and the solder resist has an opening exposing the second wiring pattern, the inner leads, and a part of the dielectric base film.

In view of the above, when the tape is applied in a COF configuration, the second wiring pattern of the tape can protect the chip from the interference of external electromagnetic waves, thus maintaining the normal operation of the COF configuration.

In order to make aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

FIG. 1A is a top view of a conventional TCP configuration.

FIG. 1B is a schematic sectional view of the TCP configuration of FIG. 1A along line A-A.

FIG. 2A is a top view of another conventional COF configuration.

FIG. 2B is a schematic sectional view of the COF configuration of FIG. 2A along line B-B.

FIG. 3A is a top view of a COF configuration according to the first embodiment of the present invention.

FIG. 3B is a schematic sectional view of the COF configuration of FIG. 3A along line C-C.

FIG. 4 is a schematic top view of a tape according to the second embodiment of the present invention.

FIG. 5 is a schematic top view of another tape according to the second embodiment of the present invention.

FIG. 6 is a schematic top view of a tape according to the third embodiment of the present invention.

FIG. 7 is a schematic top view of another tape according to the third embodiment of the present invention.

FIG. 8 is a schematic top view of a tape according to the fourth embodiment of the present invention.

FIG. 9 is a schematic top view of another tape according to the fourth embodiment of the present invention.

FIG. 10 is a schematic top view of a tape according to the fifth embodiment of the present invention.

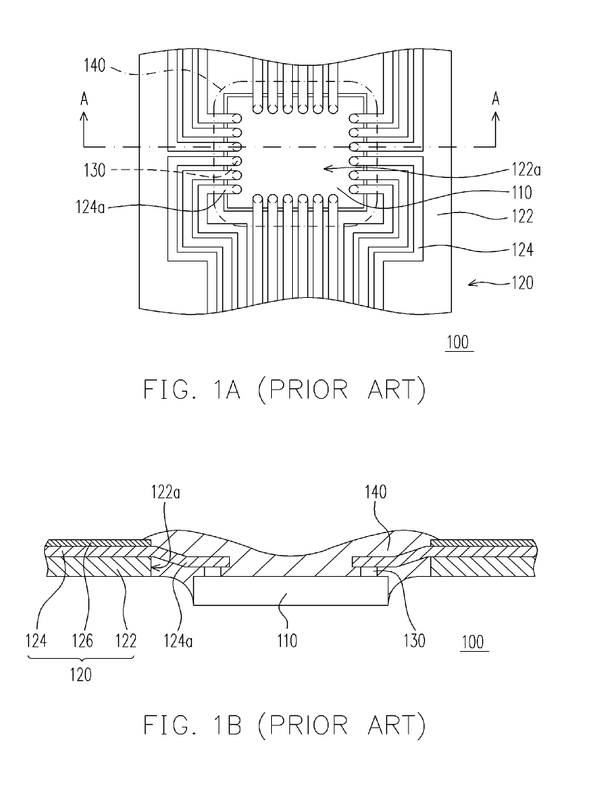

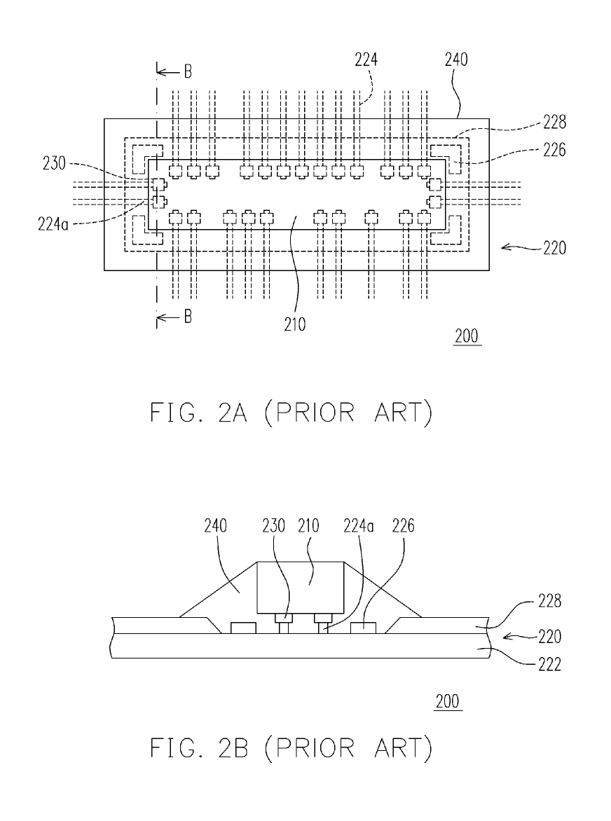

### DESCRIPTION OF EMBODIMENTS

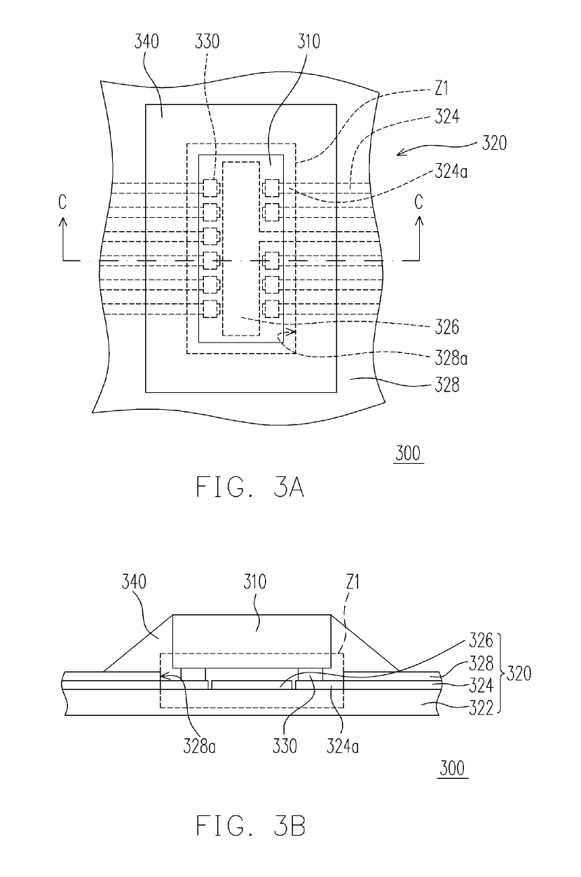

FIG. 3A is a top view of a COF configuration according to the first embodiment of the present invention. FIG. 3B is a schematic sectional view of the COF configuration of FIG. 3A along line C-C. Referring to FIGS. 3A and 3B, the COF configuration 300 comprises a chip 310 and a tape 320. The tape 320 has a chip-bonding area Z1 and comprises a dielectric base film 322 (made of, for example, polyimide), a first wiring pattern 324 (made of, for example, copper), and a second wiring pattern 326 (made of, for example, copper). The first wiring pattern 324 is disposed on the dielectric base film 322 and has a plurality of inner leads 324a disposed in the chip-bonding area Z1. The second wiring pattern 326 is disposed on the dielectric base film 322 and in the chip-bonding area. The chip 310 is electrically connected to a part of the inner leads 324a via a plurality of bumps 330 and is disposed above the second wiring pattern 326 in the chip-bonding area Z1.

In the first embodiment, the second wiring pattern 326 is, for example, rectangular, and one of the inner leads 324a is electrically connected to the second wiring pattern 326. The second wiring pattern is mainly used to prevent interference of external electromagnetic waves or prevent the chip from radiating electromagnetic waves, thus maintaining the normal operating function of the COF configuration 300. It should be noted, however, that the function of the second wiring pattern 326 is not limited to the above. Moreover, the tape 320 further comprises a solder resist 328 covering a part of the first wiring pattern 324. The solder resist 328 has an opening 328a exposing the second wiring pattern 326, the inner leads 324a, and a part of the dielectric base film 322. Furthermore, the COF configuration 300 further comprises an encapsulant 340 made of, for example, resin and encapsulating the chip 310, the inner leads 324a, the second wiring pattern 324, and the bumps 330.

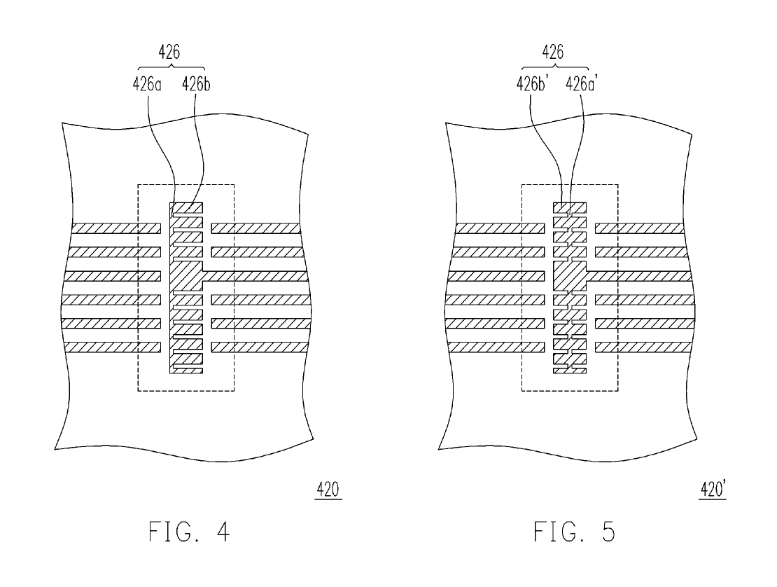

FIG. 4 is a schematic top view of a tape according to the second embodiment of the present invention. The second wiring pattern 426 of the tape 420 comprises a trunk part 426a and a plurality of protruding parts 426b electrically connected to the trunk part 426a. As seen from FIG. 4, the protruding parts 426b are disposed on one side of the trunk part 426a. Referring to FIG. 5, it is a schematic top view of another tape according to the second embodiment of the present invention. The protruding parts 426b′ of the second wiring pattern 426′ of the tape 420′ are disposed on two opposite sides of the trunk part 426a′.

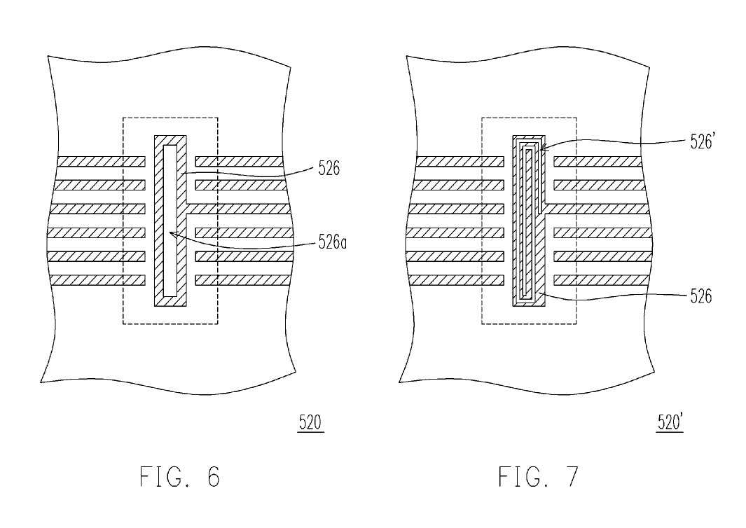

FIG. 6 is a schematic top view of a tape according to the third embodiment of the present invention. The second wiring pattern 526 of the tape 520 has a rectangular opening 526a, such that the second wiring pattern 526 appears to be a ring shape. FIG. 7 is a schematic top view of another tape according to the third embodiment of the present invention. The shape of the opening 526a′ of the second wiring pattern 526′ of the tape 520′ is spiral-shaped. It should be noted that the appearance of the openings 526a, 526a′ can be changed according to the requirements of the design and can be either a regular or an irregular shape.

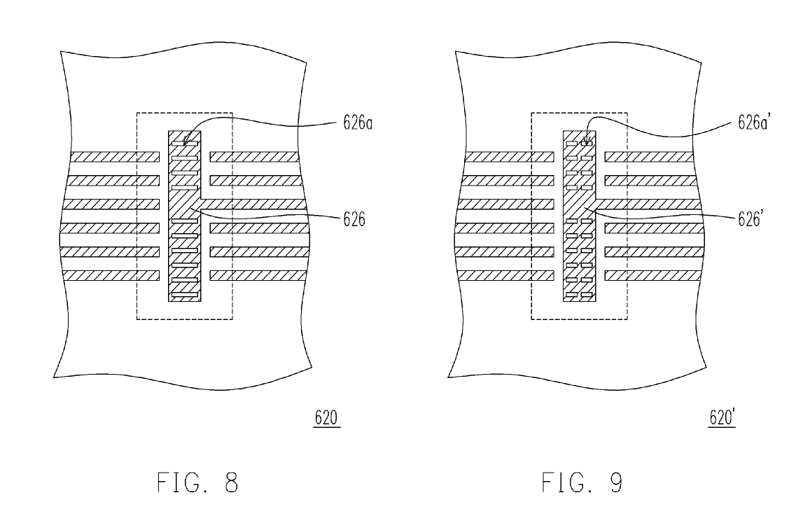

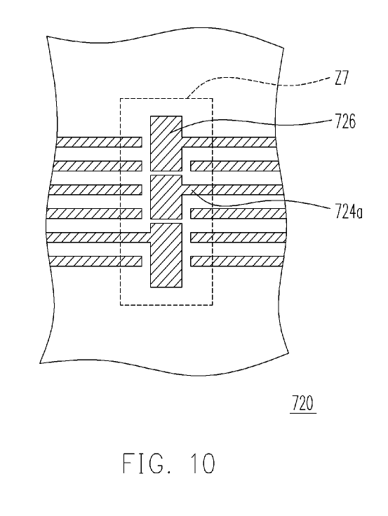

FIG. 8 is a schematic top view of a tape according to the fourth embodiment of the present invention. The second wiring pattern 626 of the tape 620 has a plurality of openings 626a arranged in one column. FIG. 9 is a schematic top view of another tape according to the fourth embodiment of the present invention. The plurality of openings 626a′ of the second wiring pattern 626′ of the tape 620′ is arranged parallel in two columns.

FIG. 10 is a schematic top view of a tape according to the fifth embodiment of the present invention. The tape 720 comprises a plurality of second wiring patterns 726 not electrically connected with each other in the chip-bonding area Z7, and each of the second wiring patterns 726 is electrically connected to one of the inner leads 724a.

Finally, it should be noted that each second wiring pattern of the aforementioned embodiments is electrically connected to one of the inner leads. However, the designer does not have to electrically connect the second wiring pattern to the inner leads, depending on the design requirements (not shown).

In view of the above, the tape of the present invention has at least the following advantages. When the tape is applied in a COF configuration, the second wiring pattern of the tape protects the chip from the interference of external electromagnetic waves and prevents the chip from radiating electromagnetic waves, thus maintaining the normal operation of the COF configuration.

It will be apparent to those skilled in the art that various modifications and variations can be made to the configuration of the present invention without departing from the scope or spirit of the invention. In view of the foregoing, it is intended that the present invention cover modifications and variations of this invention provided they fall within the scope of the following claims and their equivalents.

What is claimed is:

1. A tape with a chip-bonding area, suitable for a chip on film configuration, wherein a chip is suitable for being disposed on the tape and in the chip-bonding area, the tape comprising:
a dielectric base film;
a first wiring pattern disposed on the dielectric base film, and having a plurality of inner leads disposed in the chip-bonding area; and
at least a second wiring pattern disposed on the dielectric base film and in the chip-bonding area, wherein the chip is suitable for being electrically connected to at least a part of the inner leads and being disposed above the second wiring pattern.

2. The tape as claimed in claim 1, wherein the second wiring pattern is rectangular.

3. The tape as claimed in claim 1, wherein the second wiring pattern comprises a trunk part and a plurality of protruding parts electrically connected to the trunk part.

4. The tape as claimed in claim 3, wherein the protruding parts are disposed on one side of the trunk part.

5. The tape as claimed in claim 3, wherein the protruding parts are disposed on two opposite sides of the trunk part.

6. The tape as claimed in claim 1, wherein the second wiring pattern comprises at least one opening.

7. The tape as claimed in claim 6, wherein the opening is rectangular.

8. The tape as claimed in claim 6, wherein the opening is spiral-shaped.

9. The tape as claimed in claim 1, wherein the inner leads are not electrically connected to the second wiring pattern.

10. The tape as claimed in claim 1, wherein one of the inner leads is electrically connected to the second wiring pattern.

11. The tape as claimed in claim 1, further comprising a solder resist covering a part of the first wiring pattern, wherein the solder resist has an opening exposing the second wiring pattern, the inner leads and a part of the dielectric base film.
